(19) United States
(12) Patent Application Publication
(10) Pub. No.: US 2022/0077702 A1
(43) Pub. Date: Mar. 10, 2022

(54) BATTERY PACK, POWER TOOL, AND POWER SUPPLY METHOD THEREOF

(71) Applicant: Nanjing Chervon Industry Co., Ltd., Nanjing (CN)

(72) Inventors: Pingbo Shi, Nanjing (CN); Rong Fan, Nanjing (CN); Mingkui Lyu, Nanjing (CN)

(21) Appl. No.: 17/459,365

(22) Filed: Aug. 27, 2021

(30) Foreign Application Priority Data
Sep. 8, 2020 (CN) 202010934209.0

(51) Int. Cl. H02J 7/00; G01R 31/3842

(52) U.S. Cl. CPC H02J 7/0047; G01R 31/3842; H02J 7/0029; H02J 7/0063; H02J 7/0044; H02J 7/00714

(57) ABSTRACT

A battery pack includes a battery set, a current detection circuit, a control unit, and a current adjustment circuit. The battery set is connected to an output terminal and the output terminal is configured to connect a load. The current detection circuit is configured to detect a discharge current of the battery set. The control unit is connected to the current detection circuit and configured to determine a type of the load based on the discharge current of the battery set and to output a control signal based on the type of the load. The current adjustment circuit is connected to the control unit and configured to adjust the discharge current in response to the control signal.

### RELATED APPLICATION INFORMATION

This application claims the benefit under 35 U.S.C. § 119(a) of Chinese Patent Application No. CN 202010934209.0, filed on Sep. 8, 2020, which is incorporated by reference in its entirety herein.

### BACKGROUND

Based on the usage requirement for portability, more and more power tools currently use battery packs as a power source.

An existing battery pack for supplying power to a power tool generally includes multiple cell units connected in series and in parallel to ensure sufficient power output, so as to improve endurance of the power tool. However, with the development of battery technologies, the production of a battery pack with a higher output voltage and chemical composition and construction with lower impedance might cause the problem of compatibility with the existing power tool. A battery pack with reduced internal resistance can supply a substantially higher current to the power tool. When the current increases beyond the expectations or design constraints of a motor and electronic components in the power tool, the power tool might be burned or the power tool directly enters a protection mode after turned on and cannot be used normally.

### SUMMARY

In a first aspect, an example of the present disclosure provides a battery pack. The battery pack includes a battery set, a current detection circuit, a current adjustment circuit, and a control unit. The battery set is composed of at least one cell unit and connected to an output terminal, where the output terminal is configured to connect a load and the battery set is configured to output a power supply signal to the load through the output terminal. The current detection circuit is connected to the output terminal and configured to detect a discharge current of the battery set. The current adjustment circuit is connected between the battery set and the output terminal and configured to adjust the discharge current of the battery set. The control unit is configured to determine a type of the load based on the discharge current of the battery set within a first preset time and control, according to the type of the load, the current adjustment circuit to adjust the discharge current.

In an example, the current adjustment circuit includes a first driver circuit and a first switch tube. The first switch tube is connected in series between the battery set and the output terminal, and a control terminal of the first switch tube is connected to an output terminal of the first driver circuit. An input terminal of the first driver circuit is connected to the control unit. The first driver circuit is configured to control a time for which the first switch tube is on according to a control signal.

In an example, the current adjustment circuit includes a second driver circuit, a second switch tube, and an adjustment resistor. The second switch tube is connected in series between the battery set and the output terminal, and the adjustment resistor is connected in parallel with the second switch tube. A control terminal of the second switch tube is connected to an output terminal of the second driver circuit, and an input terminal of the second driver circuit is connected to the control unit. The second driver circuit is configured to control the second switch tube to be turned on or off according to a control signal.

In a second aspect, the examples of the present disclosure further provide a power tool. The power tool includes the battery pack of any one of the examples of the present disclosure.

In a third aspect, the examples of the present disclosure further provides a power supply method of a battery pack, where the battery pack includes a battery set configured to supply power to a load. The method includes steps described below. A current detection circuit detects a discharge current of the battery set. A control unit determines a type of the load based on the discharge current. The control unit outputs a control signal based on the type of the load. A current adjustment circuit adjusts the discharge current in response to the control signal.

In an example, the step in which the control unit determines the type of the load based on the discharge current includes steps described below. The control unit determines a rising slope of the discharge current. In the case where the rising slope of the discharge current is greater than or equal to a preset slope threshold, the control unit determines the load to be a first-type load. In the case where the rising slope of the discharge current is less than the slope threshold, the control unit determines the load to be a second-type load.

In an example, the current adjustment circuit includes a first driver circuit and a first switch tube, where the first switch tube is connected in series between the battery set and an output terminal, a control terminal of the first switch tube is connected to an output terminal of the first driver circuit, and an input terminal of the first driver circuit is connected to the control unit. The step in which the control unit outputs the control signal based on the type of the load includes a step described below. In the case where the load is a first-type load, the control unit outputs a first control signal. Correspondingly, the step in which the current adjustment circuit adjusts the discharge current in response to the control signal includes a step described below. The first driver circuit drives the first switch tube to be turned on in response to the first control signal and according to a maximum duty cycle so that the discharge current is not limited. In the case where the load is a second-type load, the control unit outputs a second control signal. Correspondingly, the step in which the current adjustment circuit adjusts the discharge current in response to the control signal includes a step described below. The first driver circuit drives the first switch tube to be turned on in response to the second control signal and according to a preset duty cycle so that the discharge current is reduced.

In an example, the current adjustment circuit includes a second driver circuit, a second switch tube, and an adjustment resistor, where the second switch tube is connected in series between the battery set and an output terminal, the adjustment resistor is connected in parallel with the second switch tube, a control terminal of the second switch tube is connected to an output terminal of the second driver circuit, and an input terminal of the second driver circuit is connected to the control unit. The step in which the control unit outputs the control signal based on the type of the load includes a step described below. In the case where the load is a first-type load, the control unit outputs a third control signal. Correspondingly, the step in which the current adjustment circuit adjusts the discharge current in response to the control signal includes a step described below. The second driver circuit drives the second switch tube to be turned on in response to the third control signal so that the discharge current is not limited. In the case where the load is a second-type load, the control unit outputs a fourth control signal. Correspondingly, the step in which the current adjustment circuit adjusts the discharge current in response to the control signal includes a step described below. The second driver circuit turns off the second switch tube in response to the fourth control signal so that the discharge current is outputted through the adjustment resistor and reduced.

In an example, after the second driver circuit turns off the second switch tube, the method further includes steps described below. The control unit outputs a fifth control signal to the second driver circuit in a preset time after the control unit outputs the fourth control signal. The second driver circuit drives the second switch tube to be turned on in response to the fifth control signal so that an output current of the battery set is not limited.

In an example, after the load is started, the method further includes steps described below. The control unit acquires an output current of the battery set through the current detection circuit. In the case where the output current is less than a preset current threshold, the control unit turns off the second switch tube at preset intervals for a discharge current through the adjustment resistor to be detected. The control unit determines a load state of the load based on the discharge current through the adjustment resistor. The second switch tube is turned on or off according to the load state.

In the examples of the present disclosure, the current detection circuit in the battery pack detects the discharge current output by the battery set, and the control unit in the battery pack determines the detected current to identify the type of the load and then adjusts the discharge current according to the type of the load. In this manner, in the case where the battery pack is adapted to an old power tool, the battery pack adjusts the discharge current through the built-in control unit so that the battery pack can start the old power tool normally. Therefore, the problem in the existing art that an old power tool to which a battery pack is applied enters starting protection is solved, and the battery pack can automatically detect the power tool and adaptively start different types of power tools based on a detection result.

### BRIEF DESCRIPTION OF DRAWINGS

FIG. 1 is a block diagram of a battery pack according to an example of the present disclosure;

FIG. 2 is a block diagram of another battery pack according to an example of the present disclosure;

FIG. 3 is a block diagram of another battery pack according to an example of the present disclosure;

FIG. 4 is a block diagram of another battery pack according to an example of the present disclosure;

FIG. 5 is a block diagram of a power tool according to an example of the present disclosure;

FIG. 6 is a flowchart of a power supply method of a battery pack according to an example of the present disclosure;

FIG. 7 is a flowchart of another power supply method of a battery pack according to an example of the present disclosure;

FIG. 8 is a schematic diagram of a flow path of a discharge current according to an example of the present disclosure; and

FIG. 9 is a schematic diagram of another flow path of a discharge current according to an example of the present disclosure.

### DETAILED DESCRIPTION

In the case where a battery pack is equipped in a power tool to supply power to the power tool, if a control unit in the battery pack determines that the power tool is an old power tool according to a detected discharge current, the control unit in the battery pack controls output characteristics of a current adjustment circuit to reduce the discharge current output by a battery set so that the discharge current output to the power tool does not exceed tolerance of the old power tool; and if the control unit determines that the power tool is a new power tool according to the discharge current, the control unit in the battery pack does not adjust the discharge current so that the power tool is smoothly started to operate. The above is the core idea of examples of the present disclosure. Technical solutions of this example are further described below in conjunction with the drawings.

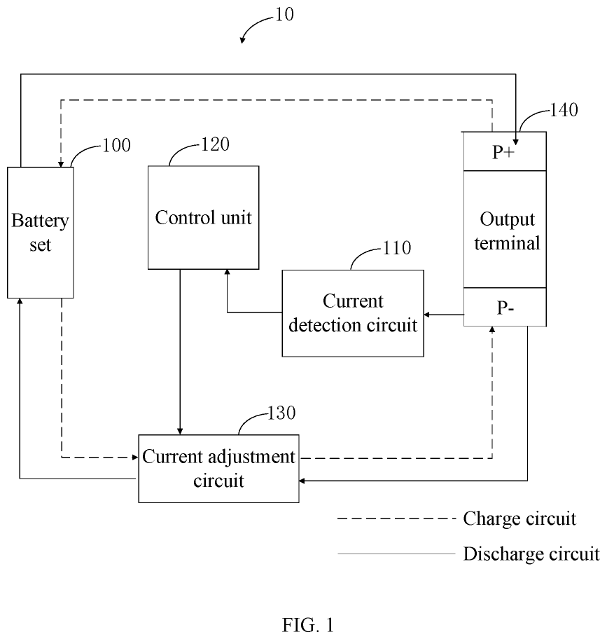

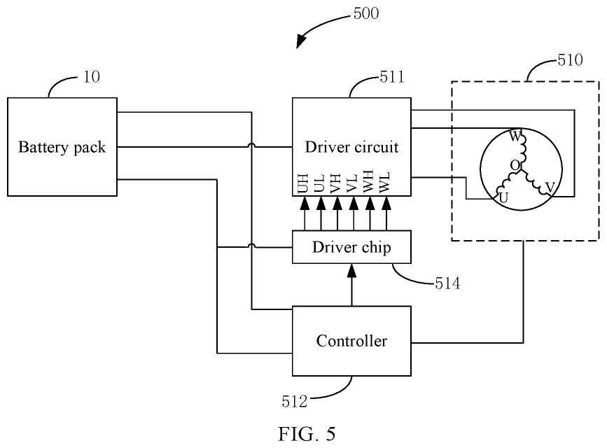

Referring to FIG. 1, a battery pack 10 may be applied to a power tool 500 (as shown in FIG. 5) for supplying power to the power tool 500. The battery pack 10 includes a battery set 100, a current detection circuit 110, a current adjustment circuit 130, and a control unit 120.

The battery set 100 is composed of at least one cell unit and connected to an output terminal 140, the output terminal 140 is configured to connect a load and the battery set 100 is configured to output power to the load through the output terminal 140. The load is the power tool 500.

The current detection circuit 110 is connected to the output terminal 140 and configured to detect a discharge current of the battery set 100.

The current adjustment circuit 130 is connected between the battery set 100 and the output terminal 140 and configured to adjust the discharge current of the battery set 100.

The control unit 120 is configured to determine a type of the load based on the discharge current of the battery set 100 within a first preset time and control, according to the type of the load, the current adjustment circuit 130 to adjust the discharge current.

In the case where the battery pack 10 is applied to the power tool 500, the battery pack 10 is generally configured to supply power to a motor of the power tool 500 so that a function part connected to the motor is driven by the motor to rotate. In this example, an example in which the power tool 500 is a new power tool or an old power tool is used for illustrating a starting control method of different types of load.

It can be known that each generation of power tool 500 undergoes technical improvements and function iterations with the development of electronic technologies. Due to the design constraints of the motor and electronic components in the power tool 500, the old power tool is designed to operate with a battery pack that outputs a low current and low power and the new power tool is designed to operate with relatively large current and power. It can be seen that the discharge currents provided by the battery pack for starting the old power tool and the new power tool are very different. Generally, when the old power tool is started, a slope of the discharge current of the battery pack rises relatively slowly; and when the new power tool is started, the slope of the discharge current of the battery pack rises relatively fast. Therefore, the control unit 120 can determine whether the power tool 500 is the old power tool or the new power tool by detecting the slope of the discharge current of the battery pack 100 when the power tool 500 is started to operate within the first preset time. Herein, in a process of starting the power tool 500, the discharge current of the battery set 100 is used for starting the power tool 500 for the power tool 500 to operate normally so that the discharge current at this stage is a starting current of the power tool 500.

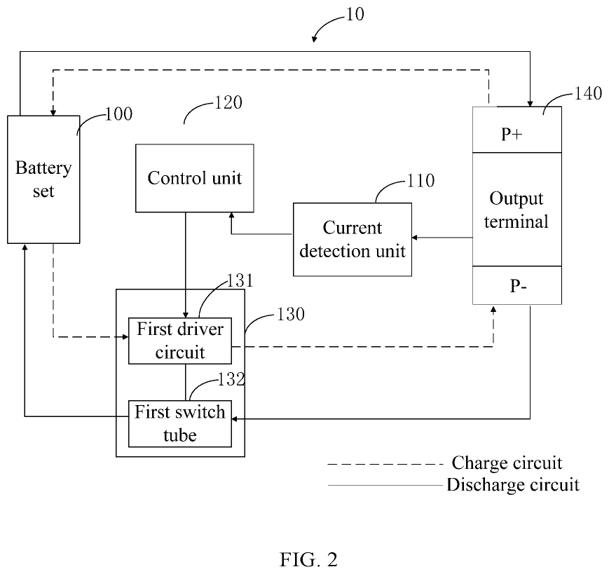

Based on the preceding technical solutions, FIG. 2 is a block diagram of another battery pack according to an example of the present disclosure. Referring to FIG. 2, the current adjustment circuit 130 includes a first driver circuit 131 and a first switch tube 132.

The first switch tube 132 is connected in series between the battery set 100 and the output terminal 140, and a control terminal of the first switch tube 132 is connected to an output terminal of the first driver circuit 131. An input terminal of the first driver circuit 131 is connected to the control unit 120. The first driver circuit 131 is configured to control a time for which the first switch tube 132 is on according to a control signal.

Specifically, the first switch tube 132 may be, for example, a metal-oxide-semiconductor (MOS) tube, and the first driver circuit 131 may be, for example, a pulse-width modulation (PWM) driver circuit. The first driver circuit 131 adjusts the time for which the first switch tube 132 is on by adjusting a duty cycle of an output signal. Since the first switch tube 132 is connected in series between the battery set 100 and the output terminal 140, an output current of the battery set 100 is adjusted when the time for which the first switch tube 132 is on changes. Specifically, in the case where the time for which the first switch tube 132 is on increases, which is equivalent to an increase of the output current of the battery set 100, the discharge current of the battery set 100 is increased, that is, the discharge current output by the battery set 100 is increased; on the contrary, in the case where the time for which the first switch tube 132 is on decreases, which is equivalent to a decrease of the output current of the battery set 100, the discharge current of the battery set 100 decreases, that is, the discharge current output by the battery set 100 is limited.

For example, the PWM driver circuit adjusts the time for which the first switch tube 132 is on. When the power tool 500 is determined to be the old power tool, the PWM driver circuit outputs a drive signal with a preset duty cycle. For example, a drive signal with a duty cycle of 93% is outputted for driving the first switch tube 132 to be turned on so that the first switch tube 132 is controlled to reduce the outputted discharge current. In this manner, the old power tool does not enter starting protection and the power tool can be started normally.

When the power tool 500 is the new power tool, the discharge current may not be limited. For example, the PWM driver circuit completely turns on the first switch tube 132, that is, drives the first switch tube 132 to be turned on according to a maximum duty cycle (100%) so that the value of the outputted discharge current is not limited and the new power tool can be started normally.

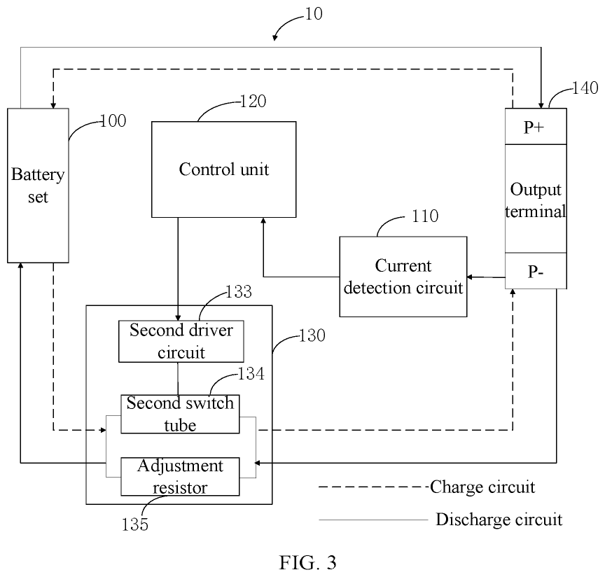

Based on the preceding technical solutions, this example further provides another current adjustment circuit 130 that adjusts the discharge current. This current adjustment circuit 130 is different from the PWM driver circuit and connects a resistor in parallel with a switch tube so that two current flow paths are formed. A flow path of the discharge current is adjusted so that the discharge current is adjusted. FIG. 3 is a block diagram of another battery pack according to an example of the present disclosure. Referring to FIG. 3, the current adjustment circuit 130 includes a second driver circuit 133, a second switch tube 134, and an adjustment resistor 135.

The second switch tube 134 is connected in series between the battery set 100 and the output terminal 140, and the adjustment resistor 135 is connected in parallel with the second switch tube 134. A control terminal of the second switch tube 134 is connected to an output terminal of the second driver circuit 133, and an input terminal of the second driver circuit 133 is connected to the control unit 120. The second driver circuit 133 is configured to control the second switch tube 134 to be turned on or off according to the control signal.

Specifically, the second switch tube 134 may be, for example, the MOS tube or an insulated-gate bipolar transistor (IGBT). The second driver circuit 133 is configured to control the second switch tube 134 to be turned on or off. The second driver circuit 133 may be, for example, a full-bridge driver circuit. The full-bridge driver circuit includes multiple electronic switches, and each electronic switch is switched on and off at a certain frequency according to the control signal from the control unit 120, thereby controlling the second switch tube 134 to be on or off.

The second switch tube 134 and the adjustment resistor 135 are arranged in parallel, thereby forming two paths for outputting currents. When the second switch tube 134 is on, the second switch tube 134 has relatively small impedance, which is equivalent to a branch of the adjustment resistor 135 being short-circuited so that the discharge current is outputted through the second switch tube 134. This operation condition may typically be that the power tool is the new power tool, the control unit 120 controls the second driver circuit to turn on the second switch tube 134, and the discharge current of the battery set 100 is outputted through the second switch tube 134, that is, the outputted discharge current is not limited so that the new power tool can be started smoothly.

When the second switch tube 134 is off, the discharge current is outputted through the branch of the adjustment resistor 135 so that the discharge current is effectively limited. This operation condition may typically be that the control unit 120 determines that the power tool is the old power tool and controls the second driver circuit 133 to turn off the second switch tube 134, and the discharge current of the battery set 100 is outputted through the adjustment resistor 135, that is, the discharge current is effectively limited by the adjustment resistor 135 so that the old power tool does not enter protection and can also be started normally.

A resistance value of the adjustment resistor 135 may be specifically adjusted according to an output parameter of the battery pack 10. In an example, the resistance value of the adjustment resistor 135 is set to 50 mQ.

In the examples of the present disclosure, the current detection circuit in the battery pack 10 detects the discharge current outputted by the battery set 100, and the control unit 120 in the battery pack 10 determines the detected current to identify the type of the load and then adjusts the discharge current according to the type of the load. In this manner, in the case where the battery pack 10 is adapted to the old power tool, the battery pack 10 adjusts the discharge current through the built-in control unit 120 so that the battery pack 10 can start the old power tool normally. Therefore, the problem in the existing art that the old power tool to which the battery pack 10 is applied enters the starting protection is solved, and the battery pack 10 can automatically detect the power tool and adaptively start different types of power tools based on a detection result.

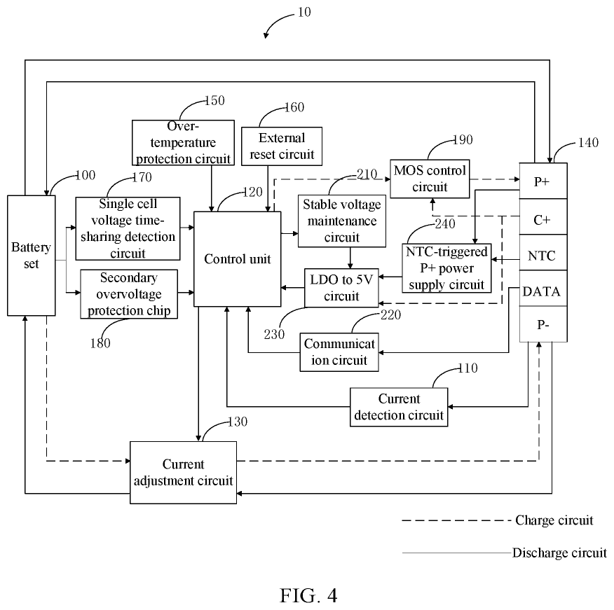

Based on the preceding examples, FIG. 4 is a block diagram of another battery pack according to an example of the present disclosure. Referring to FIG. 4, the battery pack 10 further includes an over-temperature protection circuit 150, an external reset circuit 160, a single cell voltage time-sharing detection circuit 170, a secondary overvoltage protection chip 180, an MOS control circuit 190, a stable voltage maintenance circuit 210, a low-dropout (LDO) to 5V circuit 230, a negative temperature coefficient (NTC)-triggered P+ power supply circuit 240, and a communication circuit 220.

The over-temperature protection circuit 150 is connected to the control unit 120. The over-temperature protection circuit 150 is configured to detect the temperature of each cell unit in the battery set 100 and isolate a cell unit whose temperature exceeds a set temperature threshold to perform over-temperature protection for each cell unit.

The external reset circuit 160 is connected to the control unit 120. The external reset circuit 160 is configured to receive a reset signal.

The single cell voltage time-sharing detection circuit 170 is connected in series between the control unit 120 and a corresponding cell and configured to detect a voltage of each cell unit.

The secondary overvoltage protection chip 180 is connected in series between the control unit 120 and the battery set 100.

The MOS control circuit 190 is connected to the control unit 120 and a P+ sub-terminal and a C+ sub-terminal of the output terminal separately and configured to control the P+ sub-terminal and the C+ sub-terminal to be turned on or off in response to the control unit 120.

The stable voltage maintenance circuit 210 is connected to the control unit 120 and the LDO to 5V circuit 230 separately; the LDO to 5V circuit 230 is further connected to the control unit 120, the NTC-triggered P+ power supply circuit 240, and the C+ sub-terminal of the output terminal separately; the NTC-triggered P+ power supply circuit 240 is further connected to the P+ sub-terminal and an NTC sub-terminal of the output terminal separately.

The communication circuit 220 is connected to the control unit 120 and a DATA sub-terminal of the output terminal separately.

FIG. 5 is a block diagram of the power tool 500. The power tool 500 includes the battery pack 10 provided in any example of the present disclosure. The power tool 500 is not limited to an electric drill, a grinder, a screwdriver, a sander, and the like. Referring to FIG. 5, the power tool 500 further includes a battery pack 10, an electric motor 510, a driver circuit 511, and a motor controller 512.

The battery pack 10 is configured to provide a power source for the electric motor 510.

The electric motor 510 is configured to drive a tool accessory in the power tool 500 to rotate. The electric motor 510 includes stator windings and a rotor. In some examples, the electric motor 510 is a three-phase brushless electric motor 510 and includes a rotor with a permanent magnet and three-phase stator windings U, V, and W that are commutated electronically. In some examples, the three-phase stator windings U, V, and W are connected in a star shape. In other examples, the three-phase stator windings U, V, and W are connected in a delta shape. However, it must be understood that other types of brushless motors are also within the scope of the present disclosure. The brushless motor may include less than or more than three phases.

The motor controller 512 specifically controls electronic switches in the driver circuit 511 to be on or off through a driver chip 514. The driver chip 514 controls the electronic switches in the driver circuit 511 to be on or off according to a control signal from the motor controller 512. In some examples, the control signal from the motor controller 512 is a PWM control signal. It is to be noted that the driver chip 514 may be integrated in the motor controller 512 or may be independent of the motor controller 512. In this example, an example in which the driver chip 514 is independent of the motor controller 512 is used for describing the structure of the power tool 500. A structural relationship between the driver chip 514 and the motor controller 512 is not limited in this example.

The driver circuit 511 is configured to output a drive signal to the electric motor 510 to control an operation state of the electric motor 510 and electrically connected to the battery pack 10. An input terminal of the driver circuit 511 receives a direct current (DC) pulsating voltage from the battery pack 10 and is driven by a drive signal outputted by the driver chip 514 to distribute power of the DC pulsating voltage to each phase winding on the stator of the electric motor 510 according to a certain logical relationship so that the electric motor 510 is started and generates continuous torque. Specifically, the driver circuit 511 includes multiple electronic switches. In some examples, the electronic switch includes a field-effect transistor (FET). In other examples, the electronic switch includes an IGBT and the like.

The driver circuit 511 is a circuit configured to drive the electric motor 510 to rotate by switching an energizing state of each phase winding of the electric motor 510 and controlling an energizing current of each phase winding. The order in which and the time at which phase windings are turned on depend on a position of the rotor. To rotate the electric motor 510, the driver circuit 511 has multiple driving states. In one driving state, stator windings of the electric motor 510 generate a magnetic field, the motor controller 512 outputs control signals based on different positions of the rotor to control the driver circuit 511 to switch the driving state so that the magnetic field generated by the stator windings rotates to drive the rotor to rotate, so as to drive the electric motor 510.

In addition, the power tool 500 further includes a function piece (not shown in FIG. 5), where the function piece is configured to implement the function of the power tool 500 and driven by the electric motor 510 to operate. Different power tools 500 have different function pieces. For example, for the sander, the function piece is a bottom plate that can hold sandpaper and other accessories and configured to implement a sanding function.

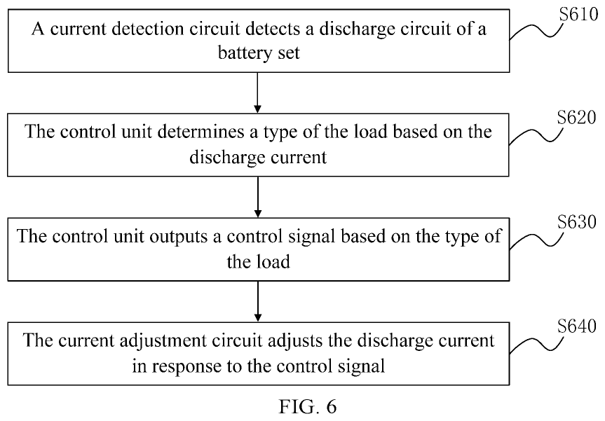

In an example, FIG. 6 is a flowchart of a power supply method of a battery pack according to an example of the present disclosure. The method may be suitable for supplying power to a power tool to automatically detect whether the power tool is an old power tool and smoothly start the old power tool by adjusting a power supply manner of the battery pack when the power tool is determined to be the old power tool. Referring to FIG. 6, the power supply method of a battery pack specifically includes steps described below.

In S610, a current detection circuit detects a discharge current of a battery set.

The discharge current is used for starting a load. For example, in the case where the battery pack is used in the power tool, the discharge current is used for starting a motor in the power tool.

The current detection circuit may be composed of, for example, a detection resistor with set accuracy and a voltage detection device. The voltage detection device is configured to detect a voltage across the detection resistor and output the detected voltage to a control unit so that the control unit calculates a current flowing through the detection resistor based on the detected voltage and a resistance value of the detection resistor, where the current is the discharge current. Of course, the current detection circuit may also be implemented in other manners, and a specific structure of the current detection circuit is not limited in this example.

In S620, the control unit determines a type of the load based on the discharge current.

Different types of loads can withstand different currents. For example, in the case where the battery pack is applied to the power tool, due to the design constraints of the motor and electronic components in the power tool, the old power tool is designed to operate with a battery pack that outputs a low current and low power and a new power tool is designed to operate with greater power. Therefore, if the power tool is the old power tool, the old power tool can withstand a relatively small discharge current so that when the battery pack outputs a relatively large discharge current, the old power tool might enter a protection mode and thus cannot be started normally.

Considering that different types of loads have different discharge current response characteristics, for example, a slope of a discharge current for the old power tool rises relatively slowly, and a slope of a discharge current for the new power tool rises relatively fast. Based on this characteristic, the control unit determines the slope of the discharge current to determine the type of the load. The process may be specifically optimized as follows.

The control unit determines a rising slope of the discharge current.

In the case where the rising slope of the discharge current is greater than or equal to a preset slope threshold, the control unit determines the load to be a first-type load.

In the case where the rising slope of the discharge current is less than the slope threshold, the control unit determines the load to be a second-type load.

Specifically, the first-type load can withstand a relatively large discharge current, while the second-type load can withstand a relatively small discharge current. For example, in the case where the battery pack is applied to the power tool, the load is the motor of the power tool. If the load is the first-type load, the power tool corresponds to the new power tool; if the load is the second-type load, the power tool corresponds to the old power tool. Therefore, the control unit can determine whether the current power tool is the new power tool or the old power tool by comparing the slope of the discharge current with the set slope threshold.

In this example, if no other description is provided, the new power tool corresponds to the first-type load, and the old power tool corresponds to the second-type load.

In S630, the control unit outputs a control signal based on the type of the load.

For different types of loads, the control unit outputs different control signals. The control signal is used for controlling a current adjustment circuit to adjust the output of the discharge current.

For example, when the load is determined to be the second-type load such as the old power tool, the control signal outputted by the control unit may reduce the outputted discharge current; and when the load is determined to be the first-type load such as the new power tool, the control signal outputted by the control unit does not limit the outputted discharge current.

In S640, the current adjustment circuit adjusts the discharge current in response to the control signal.

The current adjustment circuit can adjust a magnitude of the discharge current. An adjustment process of the discharge current is described below in detail in conjunction with a specific current adjustment circuit.

In some examples, the current adjustment circuit includes a first driver circuit and a first switch tube, where the first switch tube is connected in series between the battery set and an output terminal, a control terminal of the first switch tube is connected to an output terminal of the first driver circuit, and an input terminal of the first driver circuit is connected to the control unit.

In the case where the load is the first-type load, the control unit outputs a first control signal to the current adjustment circuit. Correspondingly, the current adjustment circuit specifically adjusts the discharge current according to a method described below.

The first driver circuit drives the first switch tube to be turned on in response to the first control signal and according to a maximum duty cycle so that the discharge current is not limited.

Specifically, since the first-type load has a relatively high capacity of withstanding the discharge current, the control unit does not need to adjust the discharge current. Under this operation condition, the first driver circuit drives the first switch tube to be turned on according to the maximum duty cycle so that the discharge current is not limited and the first-type load can be started normally.

In the case where the load is the second-type load, the control unit outputs a second control signal to the current adjustment circuit. Correspondingly, the current adjustment circuit specifically adjusts the discharge current according to a method described below.

The first driver circuit drives the first switch tube to be turned on in response to the second control signal and according to a preset duty cycle so that the discharge current is reduced.

Specifically, since the second-type load has a relatively low capacity of withstanding the discharge current, the control unit can drive the first switch tube to be turned on according to a drive signal with a constant duty cycle. The constant duty cycle may be, for example, 93%. In this manner, the outputted discharge current is reduced through the first switch tube, and the second-type load can be prevented from entering the protection mode when started and be smoothly started.

The principle of the power supply method of a battery pack is that the control unit in the battery pack determines the detected discharge current to determine the type of the load currently matching the battery pack and outputs the control signal based on the type of the load to adjust the discharge current so that the battery pack can adaptively start different types of loads.

In the power supply method of a battery pack provided in the examples of the present disclosure, the current detection circuit in the battery pack detects the discharge current of the battery pack, and the control unit determines the discharge current to determine the type of the load and outputs the corresponding control signal to the current adjustment circuit based on the type of the load so that the current adjustment circuit adjusts the discharge current correspondingly. In this example, the control unit in the battery pack can adaptively adjust the discharge current of the battery set based on the type of the load. In this manner, the following problem is solved: in the existing art, a new type of battery pack cannot match the old power tool so that the old power tool enters starting protection; and the battery pack matches different types of power tools, improving an application range of the battery pack.

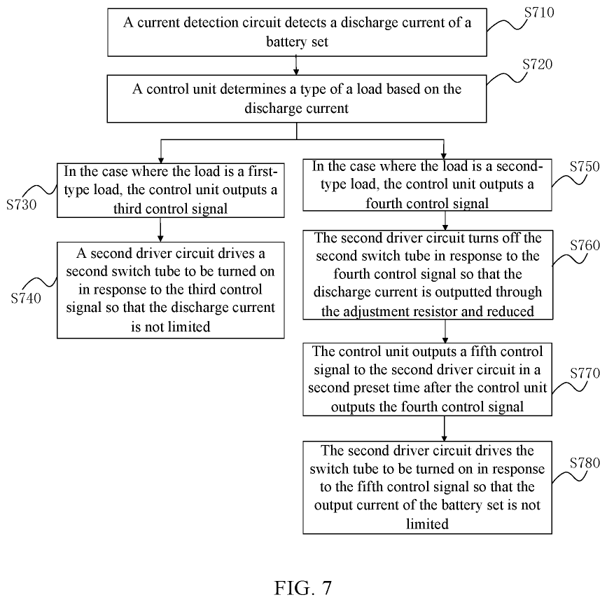

In an example, FIG. 7 is a flowchart of another power supply method of a battery pack according to an example of the present disclosure. This example is optimized on the basis of the preceding examples. The method specifically includes steps described below.

In S710, a current detection circuit detects a discharge current of a battery set.

In S720, a control unit determines a type of a load based on the discharge current.

In S730, in the case where the load is a first-type load, the control unit outputs a third control signal.

In S740, a second driver circuit drives a second switch tube to be turned on in response to the third control signal so that the discharge current is not limited.

Specifically, a current adjustment circuit includes the second driver circuit, the second switch tube, and an adjustment resistor, where the second switch tube is connected in series between the battery set and an output terminal, the adjustment resistor is connected in parallel with the second switch tube, a control terminal of the second switch tube is connected to an output terminal of the second driver circuit, and an input terminal of the second driver circuit is connected to the control unit.

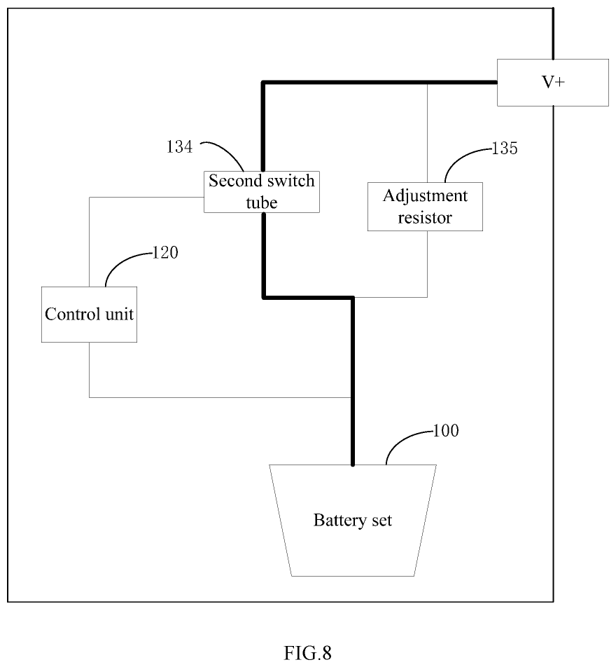

In this case, if the load is the first-type load, considering that the first-type load can withstand a relatively large discharge current, the second driver circuit turns on the second switch tube so that the discharge current is not limited and the first-type load can be started normally. FIG. 8 is a schematic diagram of a flow path of a discharge current according to an example of the present disclosure. As shown in FIG. 8, under this operation condition, the control unit 120 controls the second switch tube 134 to be turned on, the discharge current of the battery set 100 flows out through the second switch tube 134 (as shown by the thick line in the figure) to supply power to the load, and the adjustment resistor 135 is bypassed by the second switch tube 134.

In S750, in the case where the load is a second-type load, the control unit outputs a fourth control signal.

Specifically, since the second-type load cannot withstand a relatively large discharge current, the fourth control signal is used for controlling the current adjustment circuit to reduce the outputted discharge current.

In S760, the second driver circuit turns off the second switch tube in response to the fourth control signal so that the discharge current is outputted through the adjustment resistor and reduced.

Specifically, the second driver circuit turns off the second switch tube. At this time, the discharge current flows through the path of the adjustment resistor so that the discharge current is effectively limited by the adjustment resistor, and the second-type load does not enter the starting protection, solving the problem in the existing art that the battery pack does not match the load so that the load enters protection when started.

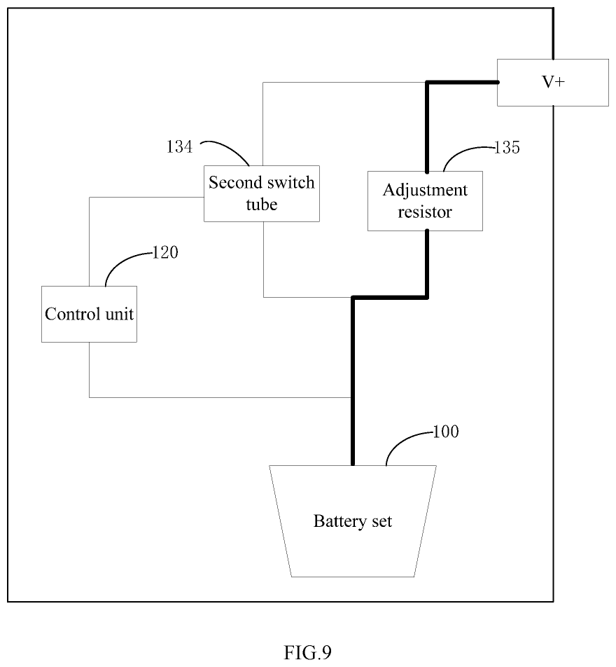

FIG. 9 is a schematic diagram of another flow path of a discharge current according to an example of the present disclosure. As shown in FIG. 9, under this operation condition, the control unit 120 controls the second switch tube 134 to be off, and the discharge current of the battery set 100 flows out through the adjustment resistor 135 (as shown by the thick line in the figure) to supply power to the load, ensuring that the second-type load is started normally.

In S770, the control unit outputs a fifth control signal to the second driver circuit in a second preset time after the control unit outputs the fourth control signal.

The second preset time is used for indicating that the load has been started and is operating normally. At this time, the output current of the battery set no longer needs to be limited so that the fifth control signal outputted by the control unit is used for controlling the second driver circuit to change an output state of the second switch tube.

In S780, the second driver circuit drives the second switch tube to be turned on in response to the fifth control signal so that the output current of the battery set is not limited.

Specifically, the second driver circuit turns on the second switch tube in response to the fifth control signal. The second switch tube has much smaller internal resistance than the adjustment resistor so that all the current basically flows through the path of the second switch tube, that is, the output current of the battery set is not limited.

In the power supply method of a battery pack provided in this example, the second switch tube is connected in parallel with the adjustment resistor, and two current paths are formed by the second switch tube and the adjustment resistor. When the control unit in the battery pack determines that the current load is the second-type load, since the second-type load can withstand a relatively small discharge current, the control unit controls the second driver circuit to turn off the second switch tube so that the discharge current of the battery set flows through the path of the adjustment resistor, the outputted discharge current is limited by the adjustment resistor, and the second-type load is prevented from entering the protection mode when started. When determining that the current load is the first-type load, the control unit controls the second driver circuit to directly turn on the second switch tube. Since the second switch tube has much smaller internal resistance than the adjustment resistor, the discharge current flows through the branch of the second switch tube, that is, the discharge current is not limited under the control of the control unit so that the first-type load can be started normally. It can be seen that in this example, the second switch tube is connected in parallel with the adjustment resistor so that under the adjustment of a control circuit in the battery pack, different types of loads can be started, expanding the application range of the battery pack.

From the preceding analysis, it can be seen that in the examples of the present disclosure, different types of loads can be started through the preceding technical solutions. On this basis, during the operation of the load, the power supply method of a battery pack further includes steps described below.

The control unit acquires the output current of the battery set through the current detection circuit.

In the case where the output current is less than a preset current threshold, the control unit turns off the second switch tube at preset intervals for a discharge current through the adjustment resistor to be detected.

The control unit determines a load state of the load based on the discharge current through the adjustment resistor.

The second switch tube is turned on or off according to the load state.

Specifically, an example in which the load is the power tool is used. During the operation of the power tool, the second switch tube is on and the current is completely outputted. At this time, if the battery pack is changed from one power tool to another power tool and the other power tool is just the old power tool, the old power tool may enter the starting protection under this operation condition if the current of the battery pack is not limited at a start-up stage.

Therefore, during the operation of the load, when the current detection circuit detects that the output current of the battery set is less than the current threshold, the control unit turns off the second switch tube at certain intervals through the second driver circuit to detect a voltage drop of the adjustment resistor so that the current flowing through the adjustment resistor is obtained. A current is generally calculated after a voltage is sampled and the second switch tube has relatively small resistance so that the current is calculated inaccurately. Therefore, the second switch tube is turned off at certain intervals so that the discharge current flows through the adjustment resistor; by this method, a more accurate output current of the battery set can be obtained, and whether the power tool is in a light-load state or a no-load state is determined. If the current flowing through the adjustment resistor is less than the set current threshold, it is determined that the power tool is in the no-load state, and the control unit in the battery pack controls the second switch tube to be turned off. In this manner, when the power tool is started, the discharge current still flows through the path of the adjustment resistor so that the outputted discharge current is limited through the adjustment resistor and thus too large a discharge current is prevented from being outputted when the power tool is restarted, where too large a discharge current causes the power tool to be damaged or fail to be started.

For example, in an example, during the operation of the power tool, when the current detection circuit detects that the current is less than a certain value within a range of 12 A to 8 A, the control unit turns off the second switch tube every 800 ms and the current detection circuit detects the current through the adjustment resistor for the control unit to determine whether the power tool is loaded.

It is to be noted that the above are merely preferred examples of the present disclosure and technical principles used therein. It is to be understood by those skilled in the art that the present disclosure is not limited to the preceding examples. Those skilled in the art can make various apparent modifications, adaptations, and substitutions without departing from the scope of the present disclosure. Therefore, while the present disclosure has been described in detail through the preceding examples, the present disclosure is not limited to the preceding examples and may include more other equivalent examples without departing from the concept of the present disclosure. The scope of the present disclosure is determined by the scope of the appended claims.

What is claimed is:

1. A battery pack, comprising:
a battery set composed of at least one cell unit and connected to an output terminal, wherein the output terminal is configured to connect a load and the battery set is configured to output a power supply signal to the load through the output terminal;
a current detection circuit connected to the output terminal and configured to detect a discharge current of the battery set;
a current adjustment circuit connected between the battery set and the output terminal and configured to adjust the discharge current of the battery set; and
a control unit configured to determine a type of the load based on the discharge current of the battery set within a first preset time and control, according to the type of the load, the current adjustment circuit to adjust the discharge current.

2. The battery pack of claim 1, wherein the current adjustment circuit comprises a first driver circuit and a first switch tube, the first switch tube is connected in series between the battery set and the output terminal, a control terminal of the first switch tube is connected to an output terminal of the first driver circuit, an input terminal of the first driver circuit is connected to the control unit, and the first driver circuit is configured to control a time for which the first switch tube is on according to a control signal output by the control unit.

3. The battery pack of claim 1, wherein the current adjustment circuit comprises a second driver circuit, a second switch tube, and an adjustment resistor, the second switch tube is connected in series between the battery set and the output terminal, the adjustment resistor is connected in parallel with the second switch tube, a control terminal of the second switch tube is connected to an output terminal of the second driver circuit, an input terminal of the second driver circuit is connected to the control unit, and the second driver circuit is configured to control the second switch tube to be turned on or off according to a control signal output by the control unit.

4. The battery pack of claim 1, wherein the control unit is configured to determine the type of the load based on a rising slope of the discharge current.

5. A power tool, comprising:
an electric motor; and
a battery pack configured to provide a power source for the electric motor;
wherein the battery pack comprises:
a battery set composed of at least one cell unit and connected to an output terminal, wherein the output terminal is configured to connect a load and the battery set is configured to output a power supply signal to the load through the output terminal;
a current detection circuit connected to the output terminal and configured to detect a discharge current of the battery set;
a current adjustment circuit connected between the battery set and the output terminal and configured to adjust the discharge current of the battery set; and
a control unit configured to determine a type of the load based on the discharge current of the battery set within a first preset time and control, according to the type of the load, the current adjustment circuit to adjust the discharge current.

6. The power tool of claim 5, wherein the current adjustment circuit comprises a first driver circuit and a first switch tube, the first switch tube is connected in series between the battery set and the output terminal, a control terminal of the first switch tube is connected to an output terminal of the first driver circuit, an input terminal of the first driver circuit is connected to the control unit, and the first driver circuit is configured to control a time for which the first switch tube is on according to a control signal output by the control unit.

7. The power tool of claim 5, wherein the current adjustment circuit comprises a second driver circuit, a second switch tube, and an adjustment resistor, the second switch tube is connected in series between the battery set and the output terminal, the adjustment resistor is connected in parallel with the second switch tube, a control terminal of the second switch tube is connected to an output terminal of the second driver circuit, an input terminal of the second driver circuit is connected to the control unit, and the second driver circuit is configured to control the second switch tube to be turned on or off according to a control signal output by the control unit.

8. The power tool of claim 5, wherein the control unit is configured to determine the type of the load based on a rising slope of the discharge current.

9. A power supply method of a battery pack, wherein the battery pack comprises a battery set and an output terminal, the battery set is configured to supply power to a load through the output terminal, and the method comprises:
detecting, by a current detection circuit of the battery pack, a discharge current of the battery set;
determining, by a control unit of the battery pack, a type of the load based on the discharge current;
outputting, by the control unit of the battery pack, a control signal based on the type of the load; and
adjusting, by a current adjustment circuit of the battery pack, the discharge current in response to the control signal.

10. The power supply method of a battery pack of claim 9, wherein determining, by the control unit of the battery pack, the type of the load based on the discharge current comprises:
determining, by the control unit of the battery pack, a rising slope of the discharge current;
in a case where the rising slope of the discharge current is greater than or equal to a preset slope threshold, determining, by the control unit of the battery pack, the load to be a first-type load; and
in a case where the rising slope of the discharge current is less than the slope threshold, determining, by the control unit of the battery pack, the load to be a second-type load.

11. The power supply method of a battery pack of claim 9, wherein the current adjustment circuit of the battery pack comprises a first driver circuit and a first switch tube, the first switch tube is connected in series between the battery set and the output terminal, a control terminal of the first switch tube is connected to an output terminal of the first driver circuit, an input terminal of the first driver circuit of the battery pack is connected to the control unit of the battery pack;
wherein outputting, by the control unit of the battery pack, the control signal based on the type of the load comprises:
in a case where the load is a first-type load, outputting, by the control unit of the battery pack, a first control signal;
wherein adjusting, by the current adjustment circuit of the battery pack, the discharge current in response to the control signal comprises:
driving, by the first driver circuit, the first switch tube to be turned on in response to the first control signal and according to a maximum duty cycle; and
in a case where the load is a second-type load, outputting, by the control unit of the battery pack, a second control signal;
wherein adjusting, by the current adjustment circuit of the battery pack, the discharge current in response to the control signal comprises:
driving, by the first driver circuit, the first switch tube to be turned on in response to the second control signal and according to a preset duty cycle.

12. The power supply method of a battery pack of claim 9, wherein the current adjustment circuit of the battery pack comprises a second driver circuit, a second switch tube, and an adjustment resistor, wherein the second switch tube is connected in series between the battery set and the output terminal, the adjustment resistor is connected in parallel with the second switch tube, a control terminal of the second switch tube is connected to an output terminal of the second driver circuit, and an input terminal of the second driver circuit is connected to the control unit of the battery pack;
wherein outputting, by the control unit of the battery pack, the control signal based on the type of the load comprises:
in a case where the load is a first-type load, outputting, by the control unit of the battery pack, a third control signal;
wherein adjusting, by the current adjustment circuit of the battery pack, the discharge current in response to the control signal comprises:
driving, by the second driver circuit, the second switch tube to be turned on in response to the third control signal; and
in a case where the load is a second-type load, outputting, by the control unit of the battery pack, a fourth control signal;
wherein adjusting, by the current adjustment circuit of the battery pack, the discharge current in response to the control signal comprises:
turning, by the second driver circuit, the second switch tube off in response to the fourth control signal.

13. The power supply method of a battery pack of claim 12, wherein after turning, by the second driver circuit, the second switch tube off, the method further comprises:
outputting, by the control unit, a fifth control signal to the second driver circuit in a second preset time after the control unit outputs the fourth control signal; and
driving, by the second driver circuit, the second switch tube to be turned on in response to the fifth control signal.

14. The power supply method of a battery pack of claim 12, wherein after the load is started, the method further comprises:
acquiring, by the control unit of the battery pack, the discharge current of the battery set through the current detection circuit;
in a case where the discharge current is less than a preset current threshold, turning, by the control unit of the battery pack, the second switch tube off at preset intervals for a discharge current through the adjustment resistor to be detected;
determining, by the control unit of the battery pack, a load state of the load based on the discharge current through the adjustment resistor; and
turning the second switch tube on or off according to the load state.
